(19) United States
(12) Patent Application Publication
(10) Pub. No.: US 2022/0199947 A1
(43) Pub. Date: Jun. 23, 2022

(54) DISPLAY DEVICE AND METHOD FOR MANUFACTURING SAME

(71) Applicant: SHARP KABUSHIKI KAISHA, Sakai City, Osaka (JP)

(72) Inventors: TOHRU OKABE, Sakai City, Osaka (JP); SHINJI ICHIKAWA, Sakai City, Osaka (JP); HIROKI TANIYAMA, Sakai City, Osaka (JP); RYOSUKE GUNJI, Sakai City, Osaka (JP); SHINSUKE SAIDA, Sakai City, Osaka (JP); HIROHARU JINMURA, Yonago-shi, Tottori (JP); AKIRA INOUE, Yonago-shi, Tottori (JP); YOSHIHIRO NAKADA, Yonago-shi, Tottori (JP)

(21) Appl. No.: 17/440,171

(22) PCT Filed: Mar. 25, 2019
(86) PCT No.: PCT/JP2019/012389

§ 371 Date: Sep. 16, 2021

(51) Int. Cl. H01L 51/52; H01L 27/32; H01L 51/56

(52) U.S. Cl. CPC H01L 51/5253; H01L 27/3246; H01L 51/0096; H01L 27/3258; H01L 2227/323; H01L 51/56

(57) ABSTRACT

A display device (50a) includes a non-display region (N) shaped in an island and provided inside a display region. The non-display region (N) includes a through hole (H) framed to penetrate the non-display region (N) along a thickness of a resin substrate (10a). In the non-display region (N), a first inorganic insulating film (11, 13, 15, 17) includes an opening (M) provided to surround the through hole (H) and penetrating the first inorganic insulating film (11, 13, 15, 17). A second inorganic insulating film (36) of a sealing film (40) is in contact with the resin substrate (10a) exposed through the opening (M) from the first inorganic insulating film (11, 13, 15, 17).

### TECHNICAL FIELD

The disclosure relates to a display device and a method for manufacturing the display device.

### BACKGROUND ART

In recent years, light-emitting organic electroluminescence (EL) display devices using organic EL elements are drawing attention as a replacement for liquid crystal display devices. An organic EL display device includes, for example: a resin substrate; a thin-film transistor (TFT) layer provided on the resin substrate; an organic EL element layer provided on the TFT layer; and a sealing film provided on the organic EL element layer. The TFT layer includes TFTs each disposed to a corresponding one of sub-pixels serving as the minimum unit of an image. The organic EL element layer includes organic EL elements arranged to correspond to the sub-pixels. The sealing film covers the organic EL elements.

Patent Document 1 discloses, for example, a display device including: an undercoat having a three-layer structure of a silicon oxide film, a silicon nitride film, and a silicon oxide film; a gate insulating film made of a silicon oxide film; a first interlayer insulating film made of a silicon nitride film; a second interlayer insulating film made of a silicon oxide film; and a circuit layer corresponding to the above TFT layer.

### CITATION LIST

### Patent Literature

[Patent Document] Japanese Unexamined Patent Application Publication No. 2018-109722

### SUMMARY

### Technical Problem

In an organic EL display device, the display region to display an image desirably includes therein a non-display region shaped into an island for installation of, for example, a camera and a fingerprint sensor. The non-display region is desirably provided with a through hole opening along the thickness of the non-display region. Here, the through hole is created in the non-display region with, for example, laser light circularly scanning and cutting the resin substrate (and various thin films formed on the resin substrate) included in the organic EL display device. Around the through hole, however, a crack might open in an inorganic insulating film included in the TFT layer.

In view of the above problem, the disclosure is intended to reduce the risk of a crack opening in an inorganic insulating film around a through hole provided to a non-display region.

### Solution to Problem

In order to accomplish the above intention, a display device according to the disclosure includes: a resin substrate; a thin-film transistor layer provided on the resin substrate, and including a first inorganic insulating film; a light-emitting element layer provided on the thin-film transistor layer, and including a plurality of light-emitting elements arranged to correspond to a plurality of sub-pixels included in a display region; a sealing film provided on the light-emitting element layer to cover the light-emitting elements, and including a second inorganic insulating film and a third inorganic insulating film stacked on top of each other in a stated order; a frame region provided around the display region; a non-display region shaped into an island and provided inside the display region; and a through hole formed to penetrate the non-display region along a thickness of the resin substrate. In the non-display region, the first inorganic insulating film includes an opening provided to surround the through hole and penetrating the first inorganic insulating film. The second inorganic insulating film is in contact with the resin substrate exposed through the opening from the first inorganic insulating film.

A method for manufacturing a display device according to the disclosure includes steps of: (a) forming a resin mother substrate on a support substrate; (b) forming a thin-film transistor layer on the resin mother substrate in a matrix, the thin-film transistor layer including a first inorganic insulating film; (c) forming a light-emitting element layer on the thin-film transistor layer in a matrix, the light-emitting element layer including a plurality of light-emitting elements arranged to correspond to a plurality of sub-pixels included in a display region; (d) forming a sealing film on the light-emitting element layer in a matrix to cover the light-emitting elements, the sealing film including a second inorganic insulating film and a third inorganic insulating film stacked on top of each other in a stated order; (e) dividing the resin mother substrate, for each of panels including the display region, into a plurality of resin substrates, step (e) succeeding step (d); and (f) forming a through hole to penetrate a non-display region along a thickness of each of the resin substrates, the non-display region being shaped into an island and provided inside the display region to be disposed to each resin substrate. Step (c) includes: (g) forming a plurality of first electrodes on the thin-film transistor layer; (h) forming an edge cover to cover a peripheral end of each of the first electrodes; (i) forming a functional layer on each of the first electrodes exposed from the edge cover; and (j) forming a second electrode to cover the functional layer. Step (c) further includes between step (h) and step (i): (k) applying a resist to a surface of a mother substrate on which the edge cover is formed; (l) patterning the resist and forming a resist pattern; and (m) etching the first inorganic insulating film exposed from the resist pattern, and forming an opening surrounding a region in which the through hole is formed and penetrating the first inorganic insulating film.

### Advantageous Effects of Invention

According to the disclosure, in the non-display region, the first inorganic insulating film is provided with the opening surrounding the through hole and penetrating the first inorganic insulating film. Such a feature makes it possible to reduce the risk of a crack opening in an inorganic insulating film around the through hole provided to the non-display region.

### BRIEF DESCRIPTION OF DRAWINGS

FIG. 1 is a plan view of a schematic configuration of an organic EL display device according to a first embodiment of the disclosure.

FIG. 2 is a plan view of a display region included in the organic EL display device according to the first embodiment of the disclosure.

FIG. 3 is a cross-sectional view of the organic EL display device, taken from line in FIG. 1.

FIG. 4 is an equivalent circuit diagram of a thin-film transistor (TFT) layer included in the organic EL display device according to the first embodiment of the disclosure.

FIG. 5 is a cross-sectional view of an organic EL layer included in the organic EL display device according to the first embodiment of the disclosure.

FIG. 6 is a cross-sectional view of a frame region included in the organic EL display device, taken from line VI-VI in FIG. 1.

FIG. 7 is a plan view of a non-display region and its surroundings included in the organic EL display device according to the first embodiment of the disclosure.

FIG. 8 is a cross-sectional view of the non-display region included in the organic EL display device, taken from line VIII-VIII in FIG. 7.

FIG. 9 is a plan view illustrating a step of applying a resist in manufacturing the organic EL display device according to the first embodiment of the disclosure.

FIG. 10 is a plan view illustrating a step of forming a resist pattern in manufacturing the organic EL display device according to the first embodiment of the disclosure.

FIG. 11 is a plan view illustrating a step of forming a sealing film in manufacturing the organic EL display device according to the first embodiment of the disclosure.

FIG. 12, corresponding to FIG. 8, is a cross-sectional view of a first modification of the organic EL display device according to the first embodiment of the disclosure.

FIG. 13, corresponding to FIG. 8, is a cross-sectional view of a second modification of the organic EL display device according to the first embodiment of the disclosure.

FIG. 14, corresponding to FIG. 8, is a cross-sectional view of a third modification of the organic EL display device according to the first embodiment of the disclosure.

FIG. 15, corresponding to FIG. 8, is a cross-sectional view of an organic EL display device according to a second embodiment of the disclosure.

### DESCRIPTION OF EMBODIMENTS

Described below in derail are embodiments of the disclosure, with reference to the drawings. Note that the disclosure shall not be limited to these embodiments.

### First Embodiment

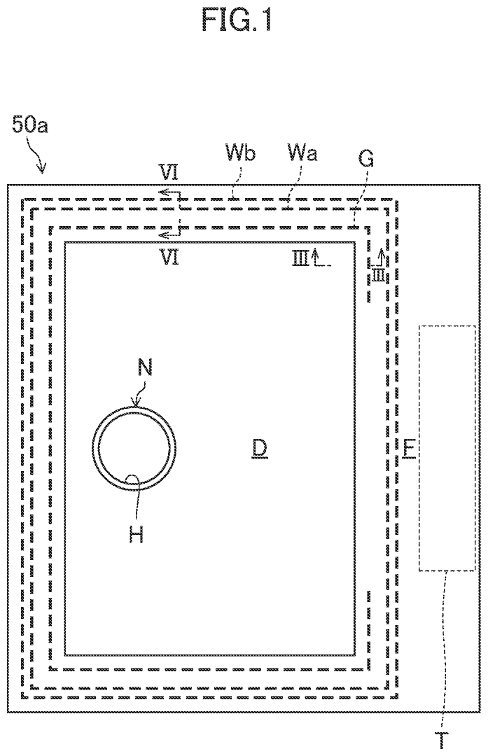

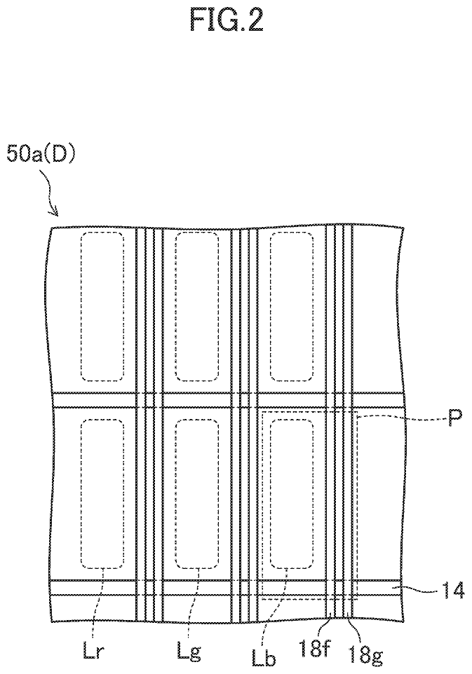

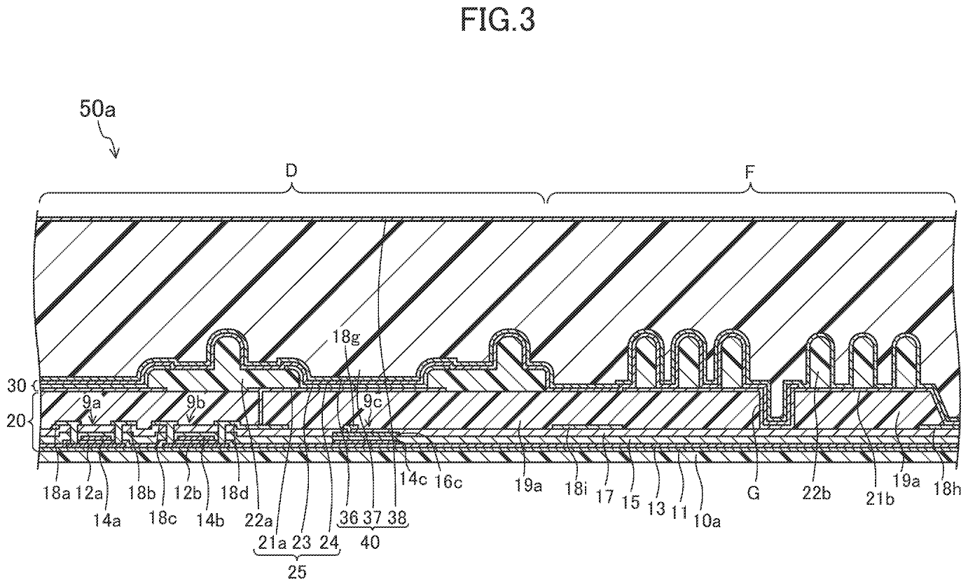

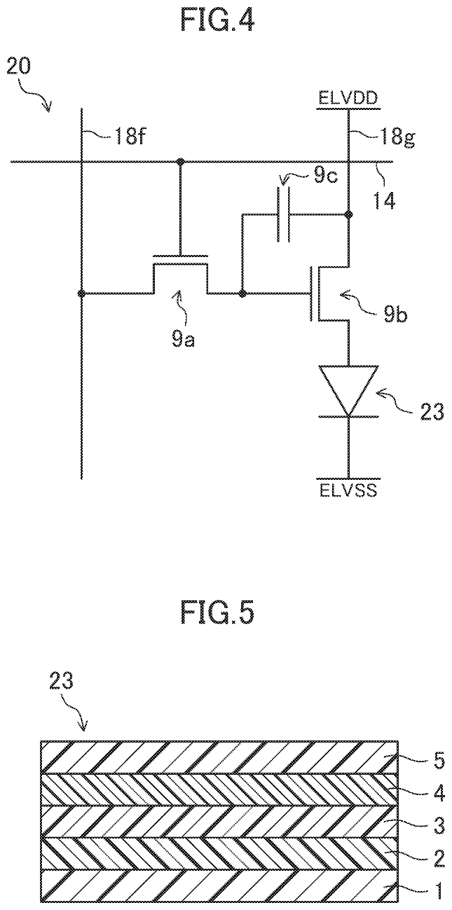

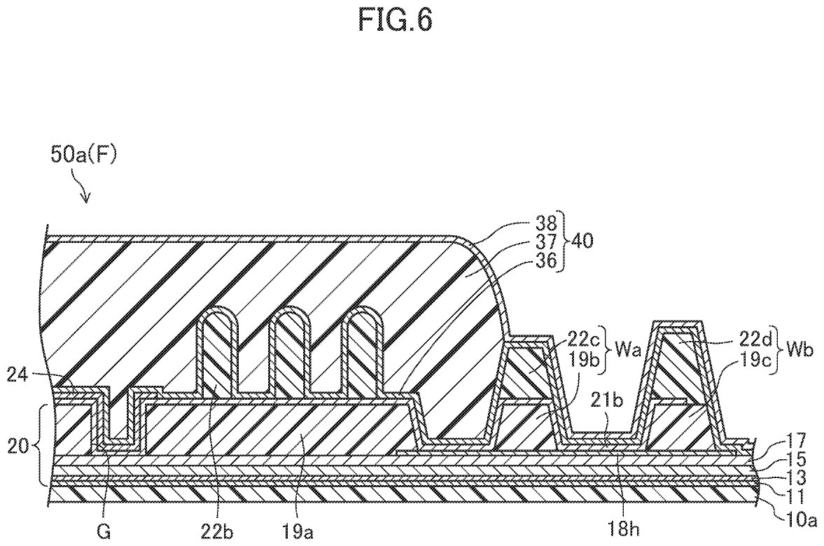

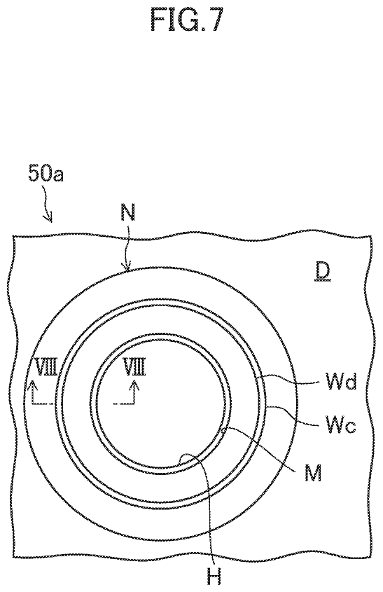

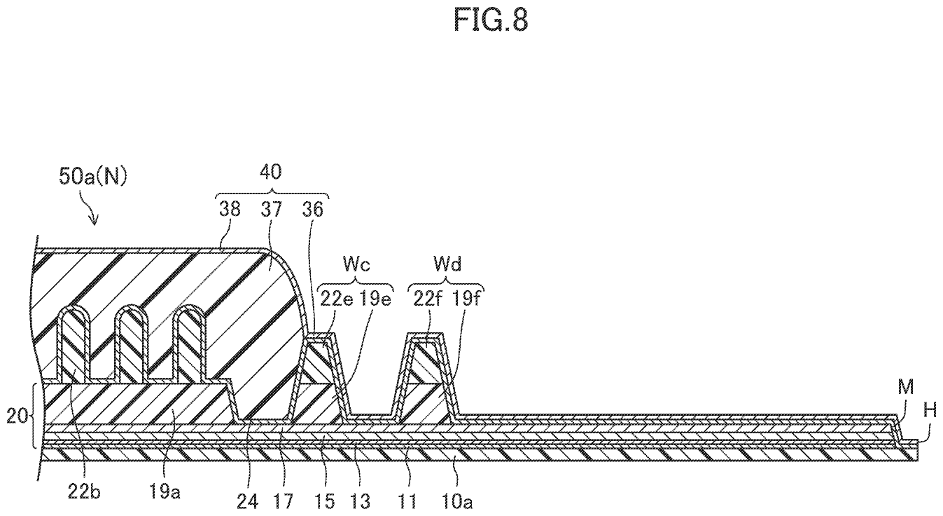

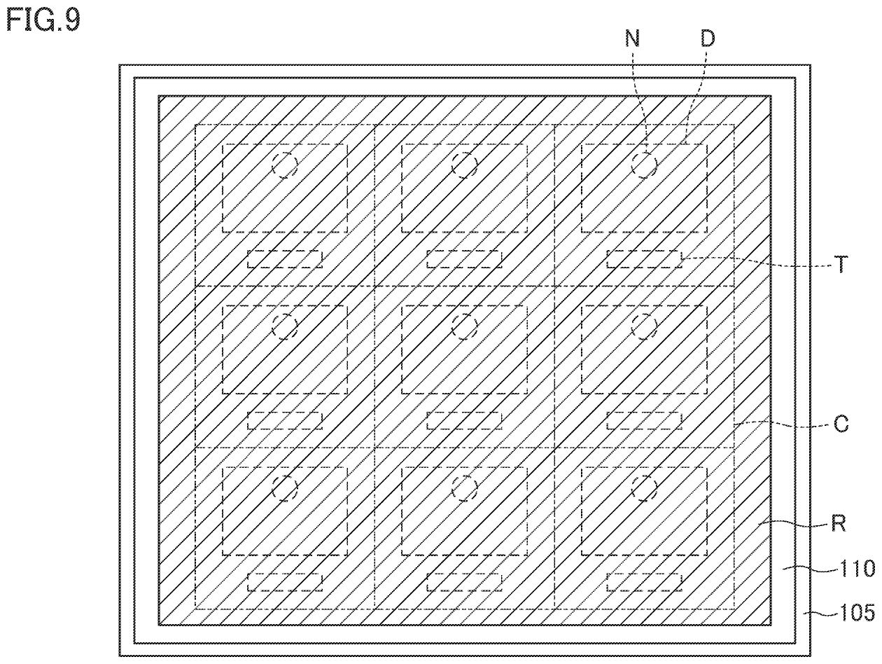

FIGS. 1 to 14 illustrate a first embodiment of a display device and a method for manufacturing the display device according to the disclosure. The embodiments below exemplify an organic EL display device including an organic EL element, as a display device including a light-emitting element. FIG. 1 is a plan view of a schematic configuration of an organic EL display device 50a according to this embodiment. FIG. 2 is a plan view of a display region D included in the organic EL display device 50a. FIG. 3 is a cross-sectional view of the organic EL display device 50a, taken from line in FIG. 1. FIG. 4 is an equivalent circuit diagram of a TFT layer 20 included in the organic EL display device 50a. FIG. 5 is a cross-sectional view of an organic EL layer 23 included in the organic EL display device 50a. FIG. 6 is a cross-sectional view of a frame region F included in the organic EL display device 50a, taken from line VI-VI in FIG. 1. FIG. 7 is a plan view of a non-display region N and its surroundings included in the organic EL display device 50a. FIG. 8 is a cross-sectional view of the non-display region N included in the organic EL display device 50a, taken from line VIII-VIII in FIG. 7.

As illustrated in FIG. 1, the organic EL display device 50a includes, for example: the display region D shaped into a rectangle and displaying an image; and the frame region F shaped into a rectangular frame and provided around the display region D. Note that, in this embodiment, the display region D is, for example, rectangular. Examples of the rectangle include such substantial rectangles as a rectangle having arc-like sides, a rectangle having rounded corners, and a rectangle having partially notched sides.

As illustrated in FIG. 2, the display region D includes a plurality of sub-pixels P arranged in a matrix. In the display region D, as illustrated in FIG. 2, for example, the sub-pixels P having red light-emitting areas Lr representing red, the sub-pixels P having green light-emitting areas Lg representing green, and the sub-pixels P having blue light-emitting areas Lb representing blue are provided next to each other. Note that, in the display region D, for example, neighboring three of the sub-pixels P each having one of a red light-emitting area Lr, a green light-emitting area Lg, and a blue light-emitting area Lb constitute one pixel. As illustrated in FIG. 1, the non-display region N is shaped into an island and provided inside the display region D. Here, as illustrated in FIG. 1, the non-display region N is provided with a through hole H for installation of, for example, a camera and a fingerprint sensor. The through hole H penetrates the non-display region N along the thickness of a resin substrate layer 10a to be described later. Note that a detailed structure of the non-display region N will be described later, with reference to FIGS. 7 and 8.

In FIG. 1, the frame region F has a right end provided with a terminal unit T extending in one direction (i.e. in a vertical direction in the drawing). Here, in the frame region F, a planarization film 19a to be described later is provided with a trench G shaped into a substantial C-shape and penetrating the planarization film 19a as illustrated in FIGS. 1, 3, and 6. Note that, as illustrated in FIG. 1, the trench G is laid into a substantial C-shape to open toward the terminal unit T in planar view. The frame region F includes a fold portion (not shown) between the display region D and the terminal unit T. The fold portion is foldable around a folding axis in a vertical direction of FIG. 1 at an angle of 180° (foldable in a U-shape).

As illustrated in FIGS. 3, 6, and 8, the organic EL display device 50a includes: a resin substrate layer 10a provided as a resin substrate; the TFT layer 20 provided on the resin substrate layer 10a; an organic EL element layer 30 provided on the TFT layer 20 and serving as a light-emitting element layer; and a sealing film 40 provided on the organic EL element layer 30.

The resin substrate layer 10a is made of, for example, polyimide resin.

As illustrated in FIGS. 3, 6, and 8, the TFT layer 20 includes: a base coat film 11; a gate insulating film 13; a first interlayer insulating film 15; and a second interlayer insulating film 17, all of which are provided in the stated order on the first inorganic insulating film and serve as a first inorganic insulating film. Furthermore, as illustrated in FIG. 3, the TFT layer 20 includes: the base coat film 11 provided on the resin substrate layer 10a; a plurality of first TFTs 9a, a plurality of second TFT 9b, and a plurality of capacitors 9c provided on the base coat film 11 and corresponding to the sub-pixels P; and the planarization film 19a provided on the first TFTs 9a, the second TFTs 9b, and the capacitors 9c. As illustrated in FIGS. 2 and 4, the TFT layer 20 includes a plurality of gate lines 14 horizontally extending in parallel with one another in the drawings. Moreover, as illustrated in FIGS. 2 and 4, the TFT layer 20 includes a plurality of source lines 18f vertically extending in parallel with one another in the drawings. Furthermore, as illustrated in FIGS. 2 and 4, the TFT layer 20 includes a plurality of power supply lines 18g vertically extending in parallel with one another in the drawings. As illustrated in FIG. 2, the power supply lines 18g and the source lines 18f are provided next to each other. In the TFT layer 20, as illustrated in FIG. 4, each of the sub-pixels P includes a first TFT 9a, a second TFT 9b, and a capacitor 9c.

The base coat film 11 is, for example, a monolayer inorganic insulating film made of such materials as silicon nitride, silicon oxide, and silicon oxide nitride, or a multilayer inorganic insulating film made of these materials.

As illustrated in FIG. 4, in each sub-pixel P, the first TFT 9a is electrically connected to the corresponding gate line 14 and source line 18f The first TFT 9a illustrated in FIG. 3 includes: a semiconductor layer 12a; a gate insulating film 13; a gate electrode 14a; a first interlayer insulating film 15; a second interlayer insulating film 17; and a source electrode 18a and a drain electrode 18b, all of which are provided on the base coat film 11 in the stated order. The semiconductor layer 12a illustrated in FIG. 3 is, for example, made of low-temperature-polysilicon film, shaped into an island, and provided on the base coat film 11. The semiconductor layer 12a includes a channel region, a source region, and a drain region. The gate insulating film 13 illustrated in FIG. 3 is provided to cover the semiconductor layer 12a. The gate electrode 14a illustrated in FIG. 3 is provided on the gate insulating film 13 to overlap the channel region of the semiconductor layer 12a. The first interlayer insulating film 15 and the second interlayer insulating film 17 illustrated in FIG. 3 are provided in the stated order to cover the gate electrode 14a. The source electrode 18a and the drain electrode 18b illustrated in FIG. 3 are spaced apart from each other on the second interlayer insulating film 17. As illustrated in FIG. 3, the source electrode 18a and the drain electrode 18b are respectively and electrically connected to the source region and the drain region of the semiconductor layer 12a through contact holes each formed in a multilayer film including the gate insulating film 13, the first interlayer insulating film 15, and the second interlayer insulating film 17. Note that the gate insulating film 13, the first interlayer insulating film 15, and the second interlayer insulating film 17 are, for example, a monolayer inorganic insulating film made of such materials as silicon nitride, silicon oxide, and silicon oxide nitride, or a multilayer inorganic insulating film made of these materials.

As illustrated in FIG. 4, in each sub-pixel P, the second TFT 9b is electrically connected to the corresponding first TFT 9a and power supply line 18g. The second TFT 9b illustrated in FIG. 3 includes: a semiconductor layer 12b; the gate insulating film 13; a gate electrode 14b; the first interlayer insulating film 15; the second interlayer insulating film 17; and a source electrode 18c and a drain electrode 18d, all of which are provided on the base coat film 11 in the stated order. The semiconductor layer 12b illustrated in FIG. 3 is, for example, made of low-temperature-polysilicon film, shaped into an island, and provided on the base coat film 11. The semiconductor layer 12b includes a channel region, a source region, and a drain region. The gate insulating film 13 illustrated in FIG. 3 is provided to cover the semiconductor layer 12b. The gate electrode 14b illustrated in FIG. 3 is provided on the gate insulating film 13 to overlap the channel region of the semiconductor layer 12b. The first interlayer insulating film 15 and the second interlayer insulating film 17 illustrated in FIG. 3 are provided in the stated order to cover the gate electrode 14b. The source electrode 18c and the drain electrode 18d illustrated in FIG. 3 are spaced apart from each other on the second interlayer insulating film 17. As illustrated in FIG. 3, the source electrode 18c and the drain electrode 18d are respectively and electrically connected to the source region and the drain region of the semiconductor layer 12b through contact holes each formed in a multilayer film including the gate insulating film 13, the first interlayer insulating film 15, and the second interlayer insulating film 17.

Note that, as an example, the first TFTs 9a and the second TFTs 9b in this embodiment are top gate TFTs. Alternatively, the first TFTs 9a and the second TFTs 9b may be bottom gate TFTs.

As illustrated in FIG. 4, in each sub-pixel P, the capacitor 9c is electrically connected to the corresponding first TFT 9a and power supply line 18g. The capacitor 9c illustrated in FIG. 3 includes: a lower conductive layer 14c formed of the same material, and in the same layer, as the gate electrodes 14a and 14b are; the first interlayer insulating film 15 provided to cover the lower conductive layer 14c; and an upper conductive layer 16c provided on the first interlayer insulating film 15 to overlap the lower conductive layer 14c. Note that the upper conductive layer 16c illustrated in FIG. 3 is electrically connected to the power supply line 18g through a contact hole formed in the second interlayer insulating film 17.

The planarization film 19a is made of, for example, a positively photosensitive resin such as polyimide resin.

The organic EL element layer 30 illustrated in FIG. 3 includes a plurality of organic EL elements 25 provided on the planarization film 19a and arranged in a matrix. The organic EL elements 25 are provided as a plurality of light-emitting elements arranged to correspond to the sub-pixels P.

Each of the organic EL elements 25 illustrated in FIG. 3 includes: a first electrode 21a provided on the planarization film 19a; the organic EL layer 23 provided on the first electrode 21a and serving as a functional layer; and a second electrode 24 provided on the organic EL layer 23 in common among the sub-pixels P.

As illustrated in FIG. 3, the first electrode 21a is electrically connected, through a contact hole formed in the planarization film 19a, to the drain electrode 18d of the second TFT 9b in each sub-pixel P. The first electrode 21a is capable of injecting holes into the organic EL layer 23. Preferably, the first electrode 21a is formed of a material having a high work function in order to improve efficiency in injecting the holes into the organic EL layer 23. Exemplary materials of the first electrode 21a include such metal materials as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Moreover, the exemplary materials of the first electrodes 21a may also include an alloy of astatine (At)/astatine dioxide (AtO₂). Furthermore, exemplary materials of the first electrode 21a may include such conductive oxides as tin oxide (SnO), zinc oxide (ZnO), indium tin oxide (ITO), and indium zinc oxide (IZO). The first electrode 21a may be a multilayer including two or more layers made of the above materials. Exemplary compound materials having a large work function include indium tin oxide (ITO) and indium zinc oxide (IZO). Furthermore, the first electrode 21a has a peripheral end covered with an edge cover 22a formed in a grid and provided in common among the sub-pixels P. Exemplary materials of the edge cover 22a include such positively photosensitive resins as polyimide resin, acrylic resin, polysiloxane resin, and novolak resin. The edge cover 22a illustrated in FIG. 3 has a surface partially serving as a pixel photo spacer. In FIG. 3, the pixel photo spacer is shaped into an island and protrudes upward. Note that, if the photo spacer such as a pixel photo spacer is formed in a different layer from that of the edge cover 22a, the photo spacer in the different layer is included in the edge covers of this embodiment.

As illustrated in FIG. 5, the organic EL layer 23 includes: a hole-injection layer 1; a hole-transport layer 2; a light-emitting layer 3; an electron-transport layer 4; and an electron-injection layer 5, all of which are provided one after another on the first electrode 21a in the stated order.

The hole injection layer 1, also referred to as an anode buffer layer, is capable of approximating the energy levels of the first electrode 21a and the organic EL layer 23 and increasing efficiency in injection of the holes from the first electrode 21a to the organic EL layer 23. Exemplary materials of the hole injection layer 1 may include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole-transport layer 2 is capable of improving efficiency in transporting the holes from the first electrode 21a to the organic EL layer 23. Exemplary materials of the hole transport-layer 2 may include porphyrin derivatives, aromatic tertiary amine compounds, styryl amine derivatives, polyvinylcarbazole, poly-p-phenylene vinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region into which the holes and the electrons are injected from the first electrode 21a and the second electrode 24 and recombine with each other, when a voltage is applied with the first electrode 21a and the second electrode 24. This light-emitting layer 3 is formed of a material with high light emission efficiency. Exemplary materials of the light-emitting layer 3 may include metal oxinoid compounds [8-hydroxyquinoline metal complexes], naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rodamine derivatives, acridine derivatives, phenoxazone, quinacridone derivatives, rubrene, poly-p-phenylene vinylene, and polysilane.

The electron-transport layer 4 is capable of efficiently transporting the electrons to the light-emitting layer 3. Exemplary materials of the electron-transport layer 4 may include, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron-injection layer 5 is capable of approximating the energy levels of the second electrode 24 and the organic EL layer 23, and increasing efficiency in injection of the electrons from the second electrode 24 to the organic EL layer 23. Such a feature makes it possible to decrease a drive voltage of the organic EL element 25. The electron-injection layer 5 may also be referred to as a cathode buffer layer. Exemplary materials of the electron-injection layer 5 may include: such inorganic alkaline compounds as lithium fluoride (LiF), magnesium fluoride magnesium fluoride (MgF2), calcium fluoride (CaF2), strontium fluoride (SrF2), and barium fluoride (BaF2); aluminum oxide (Al₂O₃); and strontium oxide (SrO).

As illustrated in FIG. 3, the second electrode 24 is provided to cover each organic EL layer 23 and the edge cover 22a. The second electrode 24 is capable of injecting electrons into the organic EL layer 23. Preferably, the second electrode 24 is made of a material having a low work function in order to improve efficiency in injection of the electrons into the organic EL layer 23. Exemplary materials of the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 24 may also be formed of an alloy of magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The second electrode 24 may also be formed of such conductive oxides as tin oxide (SnO), zinc oxide (ZnO), indium tin oxide (ITO), and indium zinc oxide (IZO). The second electrode 24 may be a multilayer including two or more layers made of the above materials. Exemplary materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and fluoride (LiF)/calcium (Ca)/aluminum (Al).

As illustrated in FIGS. 3, 6, and 8, the sealing film 40 includes: a second inorganic insulating film 36 provided to cover the second electrode 24 to cover the organic EL elements 25; an organic insulating film 37 provided on the second inorganic insulating film 36; and a third inorganic insulating film 38 provided to cover the organic insulating film 37. The sealing film 40 is capable of protecting the organic EL layers 23 from such substances as water and oxygen. The second inorganic film 36 and the third inorganic film 38 are made of such inorganic materials as silicon dioxide (SiO₂), aluminum oxide (Al₂O₃), silicon nitride (SiNx (where x is a positive integer)) such as trisilicon tetranitride (Si₃N₄), and silicon carbide nitride (SiCN). Exemplary materials of the organic insulating film 37 include such organic materials as acrylic resin, polyuria resin, parylene resin, polyimide resin, and polyamide resin.

Moreover, as illustrated in FIGS. 1 and 6, the organic EL display device 50a includes, in the frame region F: a first outer barrier wall Wa shaped into a frame and provided to surround the display region D and overlap an outer peripheral end of the organic insulating film 37; and a second outer barrier wall Wb shaped into a frame and provided to surround the first outer barrier wall Wa.

The first outer barrier wall Wa illustrated in FIG. 6 includes a lower resin layer 19b formed of the same material, and in the same layer, as the planarization film 19a is; and an upper resin layer 22c provided above the lower resin layer 19b through a first conductive layer 21b, and formed of the same material, and in the same layer, as the edge cover 22a is. Here, as illustrated in FIG. 6, the first conductive layer 21b is provided in the frame region F and shaped into a substantial C-shape to coincide with the trench G, the first outer barrier wall Wa, and the second outer barrier wall Wb. Note that the first conductive layer 21b is formed of the same material, and in the same layer, as the first electrodes 21a is.

The second outer barrier wall Wb illustrated in FIG. 6 includes a lower resin layer 19c formed of the same material, and in the same layer, as the planarization film 19a is; and an upper resin layer 22d provided above the lower resin layer 19c through the first conductive layer 21b, and formed of the same material, and in the same layer, as the edge cover 22a is.

Furthermore, as illustrated in FIGS. 3 and 6, the organic EL display device 50a includes, in the frame region F, a first frame wire 18h shaped into a substantial C-shape and provided outside the trench G to surround the display region D and coincide with the first outer barrier wall Wa and the second outer barrier wall Wb. In the terminal unit T, the first frame wire 18h is electrically connected to a power supply terminal receiving a low power-supply voltage (ELVSS). Moreover, as illustrated in FIG. 6, the first frame wire 18h is electrically connected to the second electrode 24 through the first conductive layer 21b.

Furthermore, as illustrated in FIG. 3, the organic EL display device 50a includes, in the frame area F, a second frame wire 18i shaped into a substantial C-shape and laid behind the trench G. In the terminal unit T, the second frame wire 18i is electrically connected to a power supply terminal receiving a high power-supply voltage (ELVDD). Moreover, near the display area D, the second frame wire 18i is electrically connected to the power supply lines 18g arranged in the display area D.

As illustrated in FIGS. 3, 6 and 8, the organic EL display device 50a includes, in the frame region F and the non-display region N, a plurality of peripheral photo spacers 22b each shaped into an island, provided above the planarization film 19a, and protruding upward in the drawings. Here, the peripheral photo spacers 22b are formed of the same material, and in the same layer, as the edge cover 22a is. Note that the peripheral photo spacers 22b may be a multilayer including: a resin layer formed of the same material, and in the same layer, as the edge cover 22a is; and another resin layer.

Furthermore, as illustrated in FIGS. 7 and 8, the organic EL display device 50a includes, in the non-display region N, an opening M shaped into a circular frame and provided to surround the through hole H. Here, the opening M in FIG. 8 is provided to, and penetrates, the base coat film 11, the gate insulating film 13, the first interlayer insulating film 15, and the second interlayer insulating film 17. Moreover, as illustrated in FIG. 8, the second inorganic insulating film 36 included in the sealing film 40 is in contact with a top face of the resin substrate layer 10a exposed through the opening M from the base coat film 11, the gate insulating film 13, the first interlayer insulating film 15, and the second interlayer insulating film 17. The second inorganic insulating film 36 in FIG. 8 covers a side face of the opening M provided to the base coat film 11, the gate insulating film 13, the first interlayer insulating film 15, and the second interlayer insulating film 17.

Furthermore, as illustrated in FIGS. 7 and 8, the organic EL display device 50a includes, in the non-display region N: a first inner barrier wall Wc shaped into a frame and provided to surround the opening M; and a second inner barrier wall Wd shaped into a frame and provided behind the first inner barrier wall Wc.

The first inner barrier wall Wc illustrated in FIG. 8 includes: a lower resin layer 19e formed of the same material, and in the same layer, as the planarization film 19a is; and an upper resin layer 22e provided on the lower resin layer 19e, and formed of the same material, and in the same layer, as the edge cover 22a. The first inner barrier wall Wc is provided to overlap an inner peripheral end of the organic insulating film 37.

The second inner barrier wall Wd illustrated in FIG. 8 includes a lower resin layer 19f formed of the same material, and in the same layer, as the planarization film 19a is; and an upper resin layer 22f provided on the lower resin layer 19f, and formed of the same material, and in the same layer, as the edge cover 22a is.

The above organic EL display device 50a displays an image as follows: In each sub-pixel P, a gate signal is input through the gate line 14 to the first TFT 9a. The first TFT 9a turns ON. Through the source line 18f, a data signal is written in the gate electrode 14b of the second TFT 9b and the capacitor 9c. A current in accordance with a gate voltage of the second TFT 9b is supplied from the power supply line 18g to the organic EL layer 23. Hence, the light-emitting layer 3 of the organic EL layer 23 emits light and displays the image. Note that, in the organic EL display device 50a, even if the first TFT 9a turns OFF, the gate voltage of the second TFT 9b is held in the capacitor 9c. Hence, the light-emitting layer 3 keeps emitting light until a gate signal of the next frame is input.

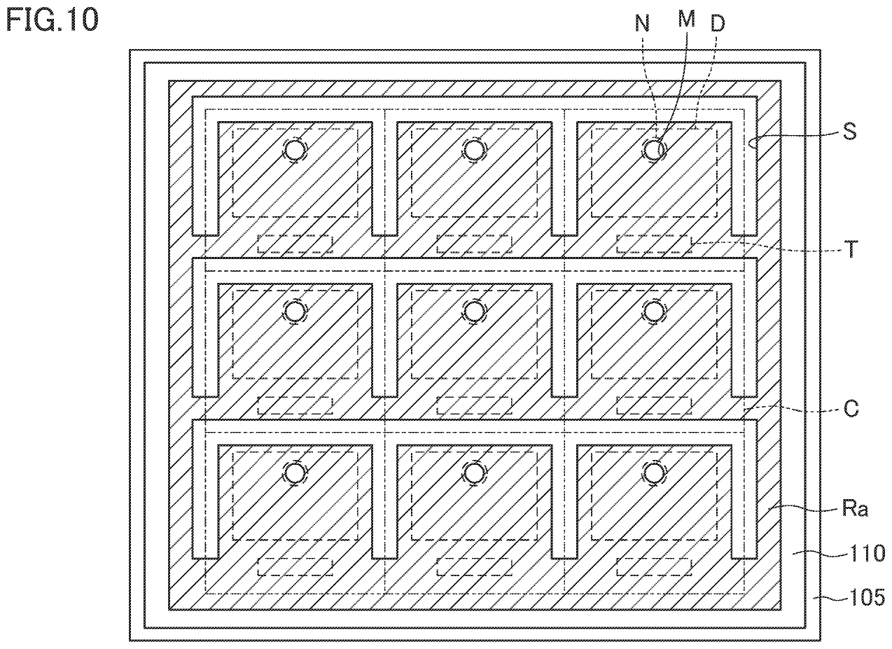

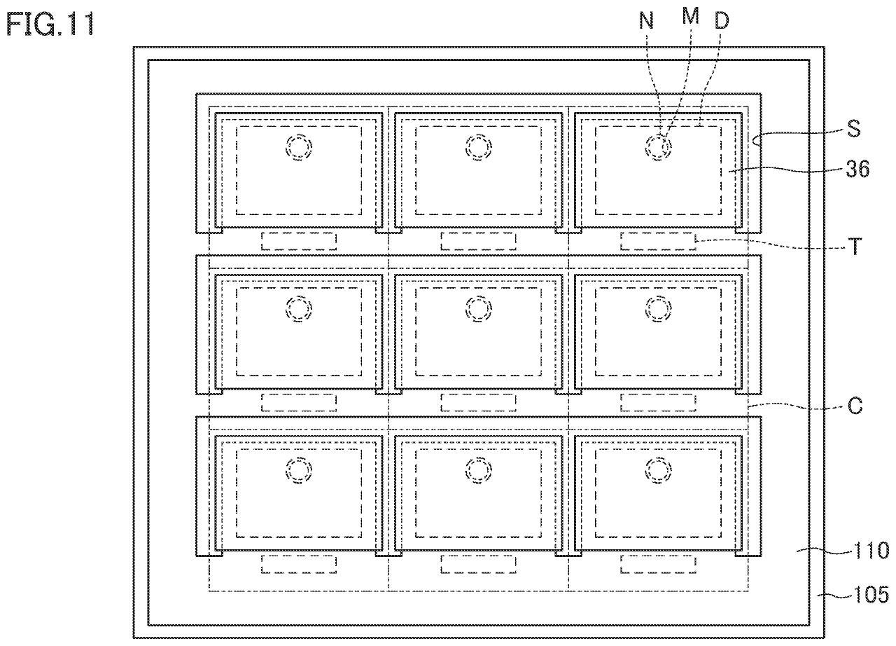

Described next is a method for manufacturing the organic EL display device 50a of this embodiment. Note that the method for manufacturing the organic EL display device 50a of this embodiment includes: a FFT layer forming step; an organic EL element layer forming step; a sealing film forming step; a dividing step; and a through hole forming step. FIG. 9 is a plan view illustrating a step of applying a resist R in the organic EL element layer forming step included in the method for manufacturing the organic EL display device 50a. FIG. 10 is a plan view illustrating a step of forming a resist pattern Ra in the organic EL element layer forming step included in the method for manufacturing the organic EL display device 50a. FIG. 11 is a plan view illustrating the sealing film forming step included in the method for manufacturing the organic EL display device 50a.

TFT Layer Forming Step

Non-photosensitive polyimide resin is applied to a support substrate 105 (see FIG. 9) such as, for example, a glass substrate. Then, a film of the applied resin is prebaked and postbaked, so that a resin mother substrate layer 110 (see FIG. 9) is formed. After that, using a known technique, the base coat film 11, the first TFTs 9a, the second TFTs 9b, the capacitors 9c, and the planarization film 19a are formed on the surface of the resin mother substrate layer 110, so that the TFT layers 20 are formed in a matrix. Hence, a TFT layer 20 is formed for each panel unit.

Organic EL Element Layer Forming Step (Light-Emitting Element Layer Forming Step)

First, a multilayer conductive film including ITO/silver alloy (a MgAg film)/ITO is deposited by, for example, sputtering on the planarization film 19a of each TFT layer 20 formed in the TFT layer forming step. After that, the multilayer conductive film is patterned by photolithography and etched, and the resist is removed. Hence, a plurality of the first electrodes 21a are formed for each panel unit (a first electrode forming step).

Next, a polyimide-based photosensitive resin film is applied by, for example, spin coating and slit coating to the surface of the mother substrate on which the first electrodes 21a are formed for each panel unit. After that, the applied film is prebaked, exposed, developed, and postbaked, so that the edge cover 22a is formed for each panel unit (an edge cover forming unit).

Furthermore, as illustrated in FIG. 9, the resist R is applied by spin coating and slit coating to the surface of the mother substrate on which the edge cover 22a is formed for each panel unit (a resist applying step).

After that, the resist R is exposed through a photo mask and deposited to be patterned. As illustrated in FIG. 10, the resist pattern Ra is formed (a resist pattern forming step).

After that, the base coat film 11, the gate insulating film 13, the first interlayer insulating film 15, and the second interlayer insulating film 17 exposed from the resist pattern Ra are removed by dry etching. Hence, for each panel unit, an opening (M) is formed in a circle to surround a region in which the through hole H is formed, and to penetrate the base coat film 11, the gate insulating film 13, the first interlayer insulating film 15, and the second interlayer insulating film 17 (an opening forming step). In the opening forming step illustrated in FIG. 10, using the resist pattern Ra, the opening (M) is formed in a circle, and a slit S is formed to penetrate the base coat film 11, the gate insulating film 13, the first interlayer insulating film 15, and the second interlayer insulating film 17. The slit S includes a prospective division line C for dividing the resin mother substrate 110 in a dividing step to be described later. Note that, as illustrated in FIG. 11, the slit S is provided for each of the panels and shaped into a U-shape opening toward the terminal unit T in plan view. The slit S is shaped into a U-shape because of the fold portion (not shown) provided between the terminal unit T and the display region D (specifically, between the terminal unit T and the second outer barrier wall Wb). In the fold portion, the base coat film 11, the gate insulating film 13, the first interlayer insulating film 15, and the second interlayer insulating film 17 are removed, and the resin mother substrate 110 is already exposed. Note that when, for example, no fold portion is provided, the slit S may be provided to surround all the edges of each panel unit.

After that, a plurality of the organic EL layers 23 (the hole-injection layers 1, the hole-transport layers 2, the light-emitting layers 3, the electron-transport layers 4, and the electron-injection layers 5) are formed by, for example, vacuum vapor deposition on the first electrodes 21a exposed from the edge cover 22a for each panel unit (an organic EL layer forming step).

Furthermore, for each panel unit, the second electrode 24 is formed by, for example, vacuum vapor deposition to cover the organic EL layers 23 in each panel unit (a second electrode forming step).

Hence, the organic EL element layers 30 are formed in a matrix.

Sealing Film Forming Step

First, on a surface of the substrate on which the organic EL element layers 30 are formed in the above organic EL element layer forming step, inorganic insulating films such as, for example, silicon nitride films, silicon oxide films, and silicon oxide nitride films are deposited by the plasma chemical vapor deposition (CVD) using a mask. As illustrated in FIG. 11, a plurality of the second inorganic insulating films 36 are formed in a matrix to come into contact with the resin mother substrate 110 exposed from the opening (M) and the slit S.

Next, on a surface of the substrate on which the second inorganic films 36 are formed, an organic resin material such as acrylic resin is applied by, for example, ink-jet printing to form a plurality of the organic insulating films 37 in a matrix.

Furthermore, on the substrate on which the organic insulating films 37 are formed, inorganic insulating films such as, for example, silicon nitride films, silicon oxide films, and silicon nitride oxide films are deposited as a plurality of the third inorganic insulating films 38 by the plasma CVD using a mask. Hence, a plurality of the sealing films 40 are formed.

Dividing Step

First, in the sealing film forming step, a protective sheet (not shown) is attached to the surface of the substrate on which the sealing films 40 are formed in the above sealing film forming step. Next, laser light is emitted to the support substrate 105 of the resin mother substrate layer 110, and the support substrate 105 is removed from a lower face of the resin mother substrate layer 110. A protective sheet (not shown) is attached to the lower face of the resin mother substrate layer 110 with the support substrate 105 removed.

Furthermore, along the prospective division line C (see the long dashed double-short dashed line in FIG. 11), laser light is emitted to the resin mother substrate layer 110 to which the protective sheet is attached. Thus, the resin mother substrate layer 110 is divided into a plurality of the resin substrate layers 10.

Through Hole Forming Step

Each of the resin substrate layers 10 that is divided into in the above separating step is provided thereon with the base coat film 11, the gate insulating film 13, the first interlayer insulating film 15, and the second interlayer insulating film 17. These films have the opening (M) formed in a circle. Such laser light as a yttrium aluminium garnet (YAG) laser is emitted, scanning circularly, inside the opening (M), and the through hole H is formed. Hence, when the through hole H is formed, the opening (M) formed in a circle and provided to the base coat film 11, the gate insulating film 13, the first interlayer insulating film 15, and the second interlayer insulating film 17 serves as the opening M shaped into a circular frame.

Through the above steps, the organic EL display device 50a of this embodiment can be produced. Note that described in this embodiment as an example is a manufacturing method in which the opening M is formed in the organic EL element layer forming step. Alternatively, in order to save the time for etching, a portion of the opening M may be formed in the gate insulating film 13, the first interlayer insulating film 15, and the second interlayer insulating film 17 when the contact holes are formed in the TFT layer forming step, and the rest of the opening M may be formed in the base coat film 11 in the organic EL element layer forming step.

Moreover, the organic EL display device 50a described in this embodiment as an example includes the base coat film 11, the gate insulating film 13, the first interlayer insulating film 15, and the second interlayer insulating film 17 laid flat in the non-display region N between the second inner barrier wall Wd and the opening M. Alternatively introduced may be organic EL display devices 50b to 50d each provided with a protruding structure between the second inner barrier wall Wd and the opening M.

Described below are the organic EL display device 50b in a first modification to the organic EL display device 50d in a third modification.

First Modification

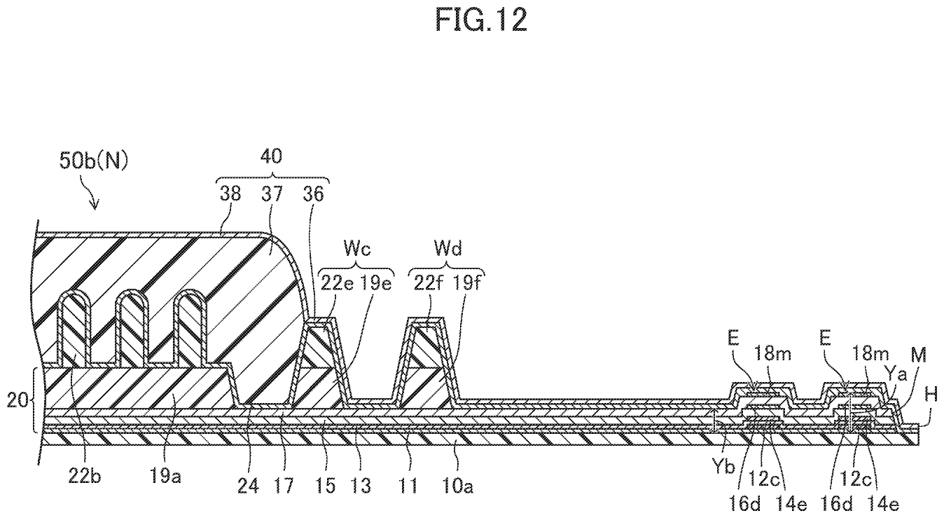

FIG. 12, corresponding to FIG. 8, is a cross-sectional view of the non-display region N in the organic EL display device 50b according to the first modification. Note that, in the modifications below, like reference signs designate identical or corresponding components in FIGS. 1 to 11. These components will not be elaborated upon.

As illustrated in FIG. 12, the organic EL display device 50b includes, in the non-display region N, a pair of multilayer thick-film portions E each shaped into a frame along an edge of the opening M, and provided between the second inner barrier wall Wd and the opening M. The display region D and the frame region F of the organic EL display device 50b are substantially the same in configuration as the display region D and the frame region F of the organic EL display device 50a in the first embodiment.

As illustrated in FIG. 12, each of the multilayer thick-film portions E includes, on the resin substrate layer 10a, a plurality of inorganic films in the stated order: the base coat film 11; a thick-film semiconductor layer 12c; the gate insulating film 13; a thick-film gate metal layer 14e; the first interlayer insulating film 15; a thick-film intermediate metal layer 16d; the second interlayer insulating film 17; and a thick-film source metal layer 18m. These inorganic films are approximately the same in acoustic compliance (volume/(density×the square of sound velocity)). The film thickness of the inorganic films are greater toward the display region D than toward the through hole H, making it possible to reduce the risk of propagation of a crack. Here, a total thickness Ya of the inorganic films (including the base coat film 11 to the thick-film source metal layer 18m) in each multilayer thick-film portion E is greater than a total thickness Yb of the inorganic films (the base coat film 11 to the second interlayer insulating film 17) between the multilayer thick-film portion E and the second inner barrier wall Wd.

The multilayer thick-film portions E included in the organic EL display device 50b are thicker than the inorganic films around the multilayer thick film portions E. Such a feature makes it possible to reduce a crack propagating into the semiconductor layer and the inorganic insulating films.

Second Modification

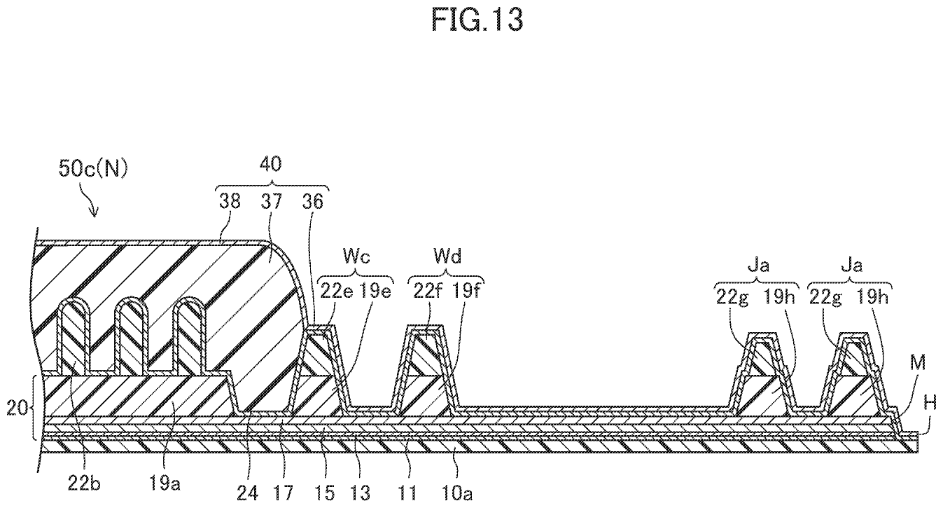

FIG. 13, corresponding to FIG. 8, is a cross-sectional view of the non-display region N in the organic EL display device 50c according to the second modification.

As illustrated in FIG. 13, the organic EL display device 50c includes, in the non-display region N, a pair of thick-film resin layers Ja each shaped into a frame along the edge of the opening M, and provided between the second inner barrier wall Wd and the opening M. The display region D and the frame region F of the organic EL display device 50c are substantially the same in configuration as the display region D and the frame region F of the organic EL display device 50a in the first embodiment.

As illustrated in FIG. 13, each of the thick-film resin layers Ja includes: a lower resin layer 19h provided on the second interlayer insulating film 17; and an upper resin layer 22g provided on the lower resin layer 19h. The lower resin layer 19h is formed of the same material, and in the same layer, as the planarization film 19a is. Furthermore, the upper resin layer 22g is formed of the same material, and in the same layer, as the edge cover 22a is.

The thick-film resin layers Ja included in the organic EL display device 50c extend a path of the second inorganic insulating film 36 and the third inorganic insulating film 38 to the display region D. Such a feature makes it possible to reduce the risk of a crack propagating into the second inorganic insulating film 36 and the third inorganic insulating film 38.

Third Modification

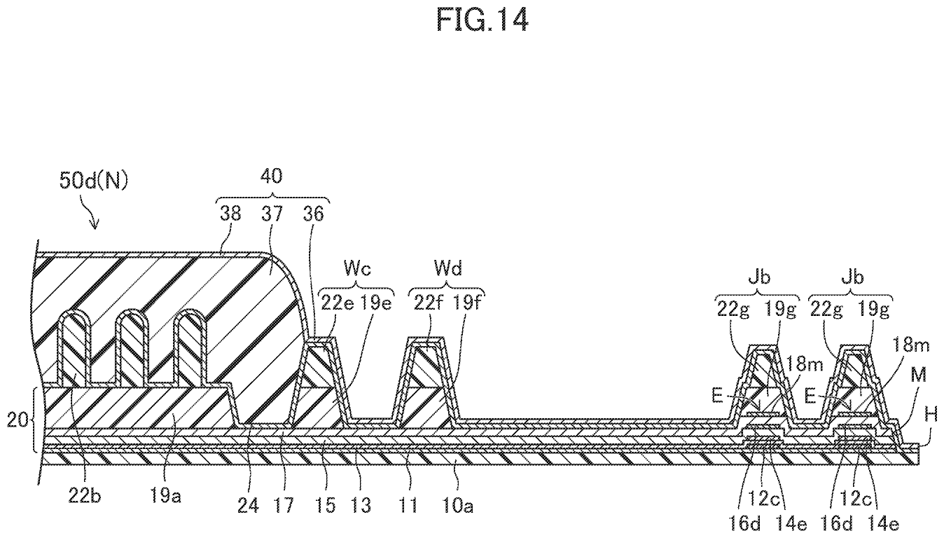

FIG. 14, corresponding to FIG. 8, is a cross-sectional view of the non-display region N in the organic EL display device 50d according to the third modification.

As illustrated in FIG. 14, the organic EL display device 50d includes in the non-display region N: a pair of the multilayer thick-film portions E each shaped into a frame along the edge of the opening M, and provided between the second inner barrier wall Wd and the opening M; and a pair of the thick-film resin layers Jb each shaped into a frame, and provided to overlap a corresponding one of the multilayer thick-film portions E in a pair. The display region D and the frame region F of the organic EL display device 50d are substantially the same in configuration as the display region D and the frame region F of the organic EL display device 50a in the first embodiment.

As illustrated in FIG. 14, each of the thick-film resin layers Jb includes: a lower resin layer 19g provided above the second interlayer insulating film 17; and an upper resin layer 22g provided on the lower resin layer 19g. The lower resin layer 19g is formed of the same material, and in the same layer, as the planarization film 19a is.

The multilayer thick-film portions E and the thick-film resin layers Ja included in the organic EL display device 50d can reduce the risk of a crack propagating into the semiconductor layer and the inorganic insulating films included in the TFT layer 20 as seen in the first modification, and into the second inorganic insulating film 36 and the third insulating film 38 included in the sealing film 40 as seen in the second modification.

Note that the above modifications describe the organic EL display devices 50b to 50d as examples. The disclosure is also applicable to an organic EL display device whose structure is a combination of the above modifications.

As can be seen, according to the organic EL display device 50a and the method for manufacturing the organic EL display device 50a of this embodiment, in the opening forming step of the organic EL element layer forming step, the opening (M) formed in a circle is provided to, and penetrates, the base coat film 11, the gate insulating film 13, the first interlayer insulating film 15, and the second interlayer insulating film 17 arranged in the non-display region N defined in a shape of an island inside the display region D. The opening (M) surrounds the through hole H formed in the through hole forming step to be carried out later. After that, in the through hole forming step, laser light is emitted, scanning circularly, inside the opening (M) formed in a circle, to cut the resin substrate layer 10a. Hence, the through hole H is formed in the non-display region N. Here, the through hole H is formed inside the opening (M) disposed in the non-display region N and shaped into a circle. Hence, the non-display region N of the organic display device 50a is provided with the opening M shaped into a circular frame and surrounding the through hole H. Hence, in the through hole forming step, none of the inorganic insulating films; namely, the base coat film 11, the gate insulating film 13, the first interlayer insulating film 15, and the second interlayer insulating film 17, is disposed to a portion to which the laser light is emitted when the through hole H is formed. Thus, even though the through hole H is formed, the base coat film 11, the gate insulating film 13, the first interlayer insulating film 15, and the second interlayer insulating film 17 are less likely to have a crack. Such features make it possible to reduce the risk of a crack opening in the base coat film 11, the gate insulating film 13, the first interlayer insulating film 15, and the second interlayer insulating film 17 around the through hole H provided to the non-display region N.

Moreover, according to the organic EL display device 50a and the method for manufacturing the organic EL display device 50a of this embodiment, the second inorganic insulating film 36 of the sealing film 40 is in contact with the top face of the resin substrate layer 10a exposed through the opening M from the base coat film 11, the gate insulating film 13, the first interlayer insulating film 15, and the second interlayer insulating film 17. Hence, the second inorganic insulating film 36 of the sealing film 40 is in contact with the side face of the opening M formed in the base coat film 11, the gate insulating film 13, the first interlayer insulating film 15, and the second interlayer insulating film 17, and with a top face of the second interlayer insulating film 17. Such a feature makes it possible to ensure sealing capability of the sealing film 40 and reduce deterioration of the organic EL elements 25.

Furthermore, according to the organic EL display device 50a and the method for manufacturing the organic EL display device 50a of this embodiment, the edge cover 22a is formed in the organic EL element layer forming step. After that, a protective resist to protect the surface of the substrate until the subsequent vapor-deposition step is used as the resist pattern Ra to be used in the opening forming step. Hence, the opening M can be formed.

In addition, according to the organic EL display device 50a and the method for manufacturing the organic EL display device 50a of this embodiment, in the opening forming step, the slit S is formed in, to penetrate, the base coat film 11, the gate insulating film 13, the first interlayer insulating film 15, and the second interlayer insulating film 17 in order to include the prospective division line C for dividing the resin mother substrate 110 in the dividing step. Hence, none of the base coat film 11, the gate insulating film 13, the first interlayer insulating film 15, and the second interlayer insulating film 17, which are disposed on the three sides of the frame region F and not along the terminal unit T, is provided along the prospective division line C. Such a feature makes it possible to reduce the risk of a crack opening in a portion of the base coat film 11, the gate insulating film 13, the first interlayer insulating film 15, and the second interlayer insulating film 17, the portion being laid along the prospective division line C.

### Second Embodiment

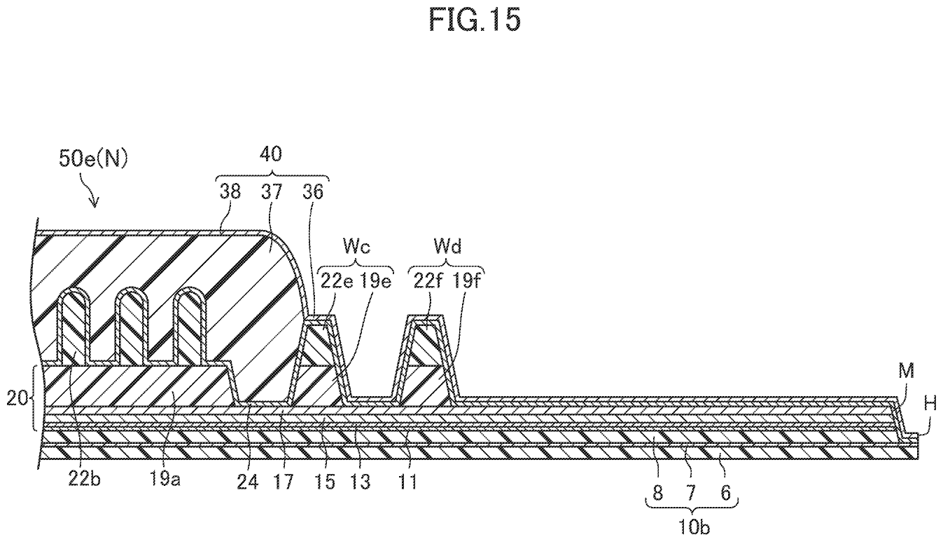

FIG. 15 illustrates a second embodiment of a display device and a method for manufacturing the display device according to the disclosure. Here, FIG. 15, corresponding to FIG. 8, is a cross-sectional view of the non-display region N of an organic EL display device 50e according to this embodiment. Note that, in the embodiments below, like reference signs designate identical or corresponding components in FIGS. 1 to 14. These components will not be elaborated upon.

Described in the first embodiment are the organic EL display devices 50a to 50d including the resin substrate layer 10a of a monolayer structure. Alternatively described in this embodiment is an organic EL display device 50e including a resin substrate layer 10b of a multilayer structure.

Similar to the organic EL display device 50a of the first embodiment, the organic EL display device 50e includes, for example, the display region D shaped into a rectangle and displaying an image, and the frame region F shaped into a rectangular frame and provided around the display region D.

As illustrated in FIG. 15, the organic EL display device 50e includes: a resin substrate layer 10b provided as a resin substrate; the TFT layer 20 provided on the resin substrate layer 10b; the organic EL element layer 30 provided on the TFT layer 20 and serving as a light-emitting element layer; and the sealing film 40 provided on the organic EL element layer 30. Here, the resin substrate layer 10b includes: a first resin substrate layer 6 provided across from the TFT layer 20 and serving as a first resin layer; a second resin substrate layer 8 provided toward the TFT layer 20 and serving as a second resin substrate; and a fourth inorganic insulating film 7 provided between the first resin substrate layer 6 and the second resin substrate layer 8. The first resin substrate layer 6 and the second resin substrate layer 8 are made of, for example, polyimide resin. The fourth inorganic insulating film 7 is, for example, a monolayer inorganic insulating film made of such materials as silicon nitride, silicon oxide, and silicon oxide nitride, or a multilayer inorganic insulating film made of these materials.

As illustrated in FIG. 15, the organic EL display device 50e includes, in the non-display region N, the opening M shaped into a circular frame and surrounding the through hole H. Here, the opening M in FIG. 15 is provided to, and penetrates, the second resin substrate layer 8, the base coat film 11, the gate insulating film 13, the first interlayer insulating film 15, and the second interlayer insulating film 17. Moreover, as illustrated in FIG. 15, the second inorganic insulating film 36 included in the sealing film 40 is in contact with the resin substrate layer 10b exposed through the opening M from the second resin substrate layer 8, the base coat film 11, the gate insulating film 13, the first interlayer insulating film 15, and the second interlayer insulating film 17. The second inorganic insulating film 36 illustrated in FIG. 15 is provided to cover a side face of the opening M in the second resin substrate layer 8, and to come into contact with a top face of the fourth inorganic insulating film 7.

The display region D and the frame region F of the organic EL display device 50e are substantially the same in configuration as the display region D and the frame region F of the organic EL display device 50a in the first embodiment.

Similar to the organic EL display device 50a of the above first embodiment, the above organic EL display device 50e is flexible, and allows, in each of the sub-pixels P, the light-emitting layer 3 of the organic EL layer 23 to appropriately emit light through the first TFTs 9a and the second TFTs 9b to display an image.

Note that this embodiment describes, as an example, the organic EL display device 50e based on the organic EL display device 50a of the above first embodiment. The disclosure is also applicable to an organic EL display device whose structure is a combination of this embodiment and the above modifications.

The organic EL display device 50e of this embodiment can be manufactured by a modification of the method for manufacturing the organic EL display device 50a of the above first embodiment.

Specifically, when the resin mother substrate layer 110 is formed in the TFT layer forming step, first, non-photosensitive polyimide resin is applied to the support substrate 105. After that, a film of the applied resin is prebaked and postbaked so that the first resin mother substrate layer (6) is formed. Next, on a surface of the substrate on which the first resin mother substrate layer (6) is formed, such a film as a silicon nitride film, a silicon oxide film, and a silicon oxide nitride film is deposited by, for example, the plasma CVD to form the fourth inorganic insulating film 7. Moreover, on a surface of the substrate on which the fourth inorganic insulating film 7 is formed, photosensitive polyimide resin is applied. After that, a film of the applied resin is prebaked, exposed, developed, and postbaked to form the second resin mother substrate layer (8). Hence, the resin mother substrate layer (10b) is formed.

Moreover, in the opening forming step of the organic EL element layer forming step, the second resin substrate layer 8, the base coat film 11, the gate insulating film 13, the first interlayer insulating film 15, and the second interlayer insulating film 17 exposed from the resist pattern Ra are removed by dry etching. Hence, for each panel unit, the opening (M) is formed in a circle to surround a region in which the through hole H is formed, and to penetrate the second resin substrate layer 8, the base coat film 11, the gate insulating film 13, the first interlayer insulating film 15, and the second interlayer insulating film 17.

Furthermore, in the sealing film forming step, on a surface of the substrate on which the organic EL element layers 30 are formed in the organic EL element layer forming step, inorganic insulating films such as silicon nitride films, silicon oxide films, and silicon oxide nitride films are deposited by the plasma chemical vapor deposition (CVD) using a mask. The second inorganic insulating films 36 are formed in a matrix to cover a side face of the opening M in the second resin substrate layer 8 and to come into contact with the top face of the fourth inorganic insulating film 7.

As can be seen, according to the organic EL display device 50e and the method for manufacturing the organic EL display device 50e of this embodiment, in the opening forming step of the organic EL element layer forming step, the opening (M) formed in a circle is provided to, and penetrates, the second resin substrate layer 8, the base coat film 11, the gate insulating film 13, the first interlayer insulating film 15, and the second interlayer insulating film 17 arranged in the non-display region N defined in a shape of an island inside the display region D. The opening (M) surrounds the through hole H formed in the through hole forming step to be carried out later. After that, in the through hole forming step, laser light is emitted, scanning circularly, inside the opening (M) formed in a circle, to cut the resin substrate layer 10b. Hence, the through hole H is formed in the non-display region N. Here, the through hole H is formed inside the opening (M) disposed in the non-display region N and shaped into a circle. Hence, the non-display region N of the organic display device 50e is provided with the opening M shaped into a circular frame and surrounding the through hole H. Hence, in the through hole forming step, none of the inorganic insulating films; namely, the base coat film 11, the gate insulating film 13, the first interlayer insulating film 15, and the second interlayer insulating film 17, is disposed to a portion to which the laser light is emitted when the through hole H is formed. Thus, even though the through hole H is formed, the base coat film 11, the gate insulating film 13, the first interlayer insulating film 15, and the second interlayer insulating film 17 are less likely to have a crack. Such features make it possible to reduce the risk of a crack opening in the base coat film 11, the gate insulating film 13, the first interlayer insulating film 15, and the second interlayer insulating film 17 around the through hole H provided to the non-display region N.

Moreover, according to the organic EL display device 50e and the method for manufacturing the organic EL display device 50e of this embodiment, the second inorganic insulating film 36 of the sealing film 40 is in contact with the top face of the fourth inorganic insulating film 7 in the resin substrate layer 10b exposed through the opening M from the second resin substrate layer 8, the base coat film 11, the gate insulating film 13, the first interlayer insulating film 15, and the second interlayer insulating film 17. Hence, the second inorganic insulating film 36 of the sealing film 40 is in contact with the top face of the fourth inorganic insulating film 7, with the side face of the opening M formed in the base coat film 11, the gate insulating film 13, the first interlayer insulating film 15, and the second interlayer insulating film 17, and with a top face of the second interlayer insulating film 17. Such a feature makes it possible to ensure sealing capability of the sealing film 40 and reduce deterioration of the organic EL elements 25.

Furthermore, according to the organic EL display device 50e and the method for manufacturing the organic EL display device 50e of this embodiment, the side face of the opening M in the second resin substrate layer 8 is covered with the second inorganic insulating film 36 of the sealing film 40. Such a feature makes it possible to keep foreign objects including water from entering the second resin substrate layer 8, and reduce deterioration of the organic EL elements 25.

### OTHER EMBODIMENTS

In the above embodiments, the organic EL layer is formed of a multilayer including such five layers as the hole-injection layer, the hole-transport layer, the light-emitting layer, the electron-transport layer, and the electron-injection layer. Alternatively, the organic EL layer may be formed of a multilayer including such three layers as a hole-injection and hole-transport layer, the light-emitting layer, and an electron-transport and electron-injection layer.

Moreover, in the organic EL display devices of the above embodiments described as examples, the first electrode is an anode and the second electrode is a cathode. Alternatively, the disclosure is applicable to an organic EL display device including an organic EL layer whose multilayered structure is inverted so that the first electrode is a cathode and the second electrode is an anode.

Furthermore, in the organic EL display devices of the above embodiments described as examples, the electrodes of the TFTs connected to the first electrodes are drain electrodes. Alternatively, the disclosure is applicable to an organic EL display device in which the electrodes of the TFTs connected to the first electrodes are referred to as source electrodes.

In addition, in the organic EL display devices 50a to 50e of the above embodiments described as examples, the through hole H is shaped into a circle in plan view. Alternatively, the through hole H may be, for example, shaped into such a polygon as a rectangle in plan view.

Moreover, the above embodiments describe as examples the organic EL display devices 50a to 50e each including the sealing film 40 in which the organic insulating film 37 is provided between the second inorganic insulating film 36 and the third inorganic insulating film 38. Alternatively, the disclosure can also be applied to an organic EL display device including an organic vapor-deposited film formed between the second inorganic insulating film 36 and the third inorganic insulating film 38, and the organic vapor-deposited film is treated with a plasma ashing process to block foreign substances. Even if foreign substances are found on the display region, such a sealing film can ensure sealability with the third inorganic insulating film, making it possible to improve reliability.

In addition, the display devices of the embodiments described as examples are organic EL display devices. Alternatively, the disclosure is applicable to a display device including a plurality of light-emitting elements driven by a current. For example, the disclosure is applicable to a display device including quantum-dot light emitting diodes (QLEDs); that is, light-emitting elements using layers containing quantum dots.

### INDUSTRIAL APPLICABILITY

As can be seen, the disclosure is applicable to a flexible display device.

1. (canceled)

2. (canceled)

3. A display device, comprising:
a resin substrate;
a thin-film transistor layer provided on the resin substrate, and including a first inorganic insulating film;
a light-emitting element layer provided on the thin-film transistor layer, and including a plurality of light-emitting elements arranged to correspond to a plurality of sub-pixels included in a display region;
a sealing film provided on the light-emitting element layer to cover the light-emitting elements, and including a second inorganic insulating film and a third inorganic insulating film stacked on top of each other in a stated order;
a frame region provided around the display region;
a non-display region shaped into an island and provided inside the display region; and
a through hole formed to penetrate the non-display region along a thickness of the resin substrate,
in the non-display region, the first inorganic insulating film including an opening provided to surround the through hole and penetrating the first inorganic insulating film, and
the second inorganic insulating film being in contact with the resin substrate exposed through the opening from the first inorganic insulating film, wherein
the resin substrate includes: a first resin substrate provided across from the thin-film transistor layer; a second resin substrate provided toward the thin-film transistor layer; and a fourth inorganic insulating film provided between the first resin substrate and the second resin substrate,
the opening is provided to, and penetrates, the second resin substrate, and
the second inorganic insulating film is provided to cover a side face, of the second resin substrate, toward the through hole, and to come into contact with a top face of the fourth inorganic insulating film.

4. The display device according to claim 3, wherein
the sealing film includes an organic insulating film provided between the second inorganic insulating film and the third inorganic insulating film,
the non-display region includes an inner barrier wall shaped into a frame and provided to surround the opening and overlap an inner peripheral end of the organic insulating film, and
the frame region includes an outer barrier wall shaped into a frame and provided to surround the display region and overlap an outer peripheral end of the organic insulating film.

5. The display device according to claim 4, wherein
the thin-film transistor layer includes a plurality of inorganic films,
the display device further comprises a multilayer thick-film portion shaped into a frame along an edge of the opening, and provided between the inner barrier wall and the opening, the multilayer thick-film portion including the inorganic films stacked on top of another, and
a total thickness of the inorganic films in the multilayer thick-film portion is greater than a total thickness of the inorganic films between the multilayer thick-film portion and the inner barrier wall.

6. The display device according to claim 5, wherein
the inorganic films include the first inorganic insulating film.

7. The display device according to claim 6, wherein
the inorganic films include a thick-film semiconductor layer formed of the same material, and in the same layer, as a semiconductor layer included in the thin-film transistor layer is.

8. The display device according to claim 6, wherein
the inorganic films include a thick-film metal layer formed of the same material, and in the same layer, as a metal layer included in the thin-film transistor layer is.

9. The display device according to claim 5, further comprising
a thick-film resin layer shaped into a frame, and provided on, and overlapping, the multilayer thick-film portion.

10. The display device according to claim 9, wherein
the thin-film transistor layer includes a planarization film provided toward the light-emitting element layer,
each of the light-emitting elements includes: a first electrode; a functional layer; and a second electrode stacked on top of another in a stated order,
the light-emitting element layer includes an edge cover provided to cover a peripheral end of the first electrode in each of the light-emitting elements, and
the thick-film resin layer includes: a lower resin layer formed of the same material, and in the same layer, as the planarization film is; and an upper resin layer formed of the same material, and in the same layer, as the edge cover is.

11. The display device according to claim 4, further comprising
a thick-film resin layer shaped into a frame along an edge of the opening, and provided between the inner barrier wall and the opening.

12. The display device according to claim 11, wherein
the thin-film transistor layer includes a planarization film provided toward the light-emitting element layer,
each of the light-emitting elements includes: a first electrode; a functional layer; and a second electrode stacked on top of another in a stated order,
the light-emitting element layer includes an edge cover provided to cover a peripheral end of the first electrode in each of the light-emitting elements, and
the thick-film resin layer includes: a lower resin layer formed of the same material, and in the same layer, as the planarization film is; and an upper resin layer formed of the same material, and in the same layer, as the edge cover is.

13. The display device according to claim 3, wherein
each of the light-emitting elements is an organic electroluminescence element.

14. A method for manufacturing a display device, the method comprising steps of:
(a) forming a resin mother substrate on a support substrate;
(b) forming a thin-film transistor layer on the resin mother substrate in a matrix, the thin-film transistor layer including a first inorganic insulating film;
(c) forming a light-emitting element layer on the thin-film transistor layer in a matrix, the light-emitting element layer including a plurality of light-emitting elements arranged to correspond to a plurality of sub-pixels included in a display region;
(d) forming a sealing film on the light-emitting element layer in a matrix to cover the light-emitting elements, the sealing film including a second inorganic insulating film and a third inorganic insulating film stacked on top of each other in a stated order;
(e) dividing the resin mother substrate, for each of panels including the display region, into a plurality of resin substrates, step (e) succeeding step (d); and
(f) forming a through hole to penetrate a non-display region along a thickness of each of the resin substrates, the non-display region being shaped into an island and provided inside the display region to be disposed to each resin substrate,
step (c) including:
(g) forming a plurality of first electrodes on the thin-film transistor layer;
(h) forming an edge cover to cover a peripheral end of each of the first electrodes;
(i) forming a functional layer on each of the first electrodes exposed from the edge cover; and
(j) forming a second electrode to cover the functional layer, and
step (c) further including between step (h) and step (i):
(k) applying a resist to a surface of a mother substrate on which the edge cover is formed;
(l) patterning the resist and forming a resist pattern; and
(m) etching the first inorganic insulating film exposed from the resist pattern, and forming an opening surrounding a region in which the through hole is formed and penetrating the first inorganic insulating film.

15. The method according to claim 14, wherein
the resin substrate includes: a first resin substrate provided across from the thin-film transistor layer; a second resin substrate provided toward the thin-film transistor layer; and a fourth inorganic insulating film provided between the first resin substrate and the second resin substrate, and
in step (m), the opening is formed to surround the through hole and penetrate the second resin substrate.

16. The method according to claim 14, wherein
in step (d), the second inorganic insulating film is formed to come into contact with the resin mother substrate exposed from the opening.

17. The method according to claim 15, wherein
in step (d), the second inorganic insulating film is formed to cover a side face of the opening in the second resin substrate, and to come into contact with a top face of the fourth inorganic insulating film.

18. The method according to claim 14, wherein
in step (m), a slit is formed in the first inorganic insulating film to penetrate the first inorganic insulating film, the slit including a prospective division line for dividing the resin mother substrate in step (e).

19. The method according to claim 18, wherein
the display region is surrounded with a frame region,
the frame region has an end provided with a terminal unit, and
in step (m), the slit is provided for each of the panels, and shaped into a U-shape opening toward the terminal unit in plan view.

20. The method according to claim 14, wherein
each of the light-emitting elements is an organic electroluminescence element.
